(19) United States
(12) Patent Application Publication
(10) Pub. No.: US 2008/0257867 A1
(43) Pub. Date: Oct. 23, 2008

(54) Apparatus and Method for Nano-Scale Electric Discharge Machining

(76) Inventors: Ajay P Malshe, Springdale, AR (US); Kumar R. Virwani, Fayetteville, AR (US); Kalmakar P. Rajurkar, Lincoln, NE (US)

Correspondence Address: MORRIS MANNING MARTIN LLP, 3343 PEACHTREE ROAD, NE, 1600 ATLANTA FINANCIAL CENTER, ATLANTA, GA, 30326, US

(21) Appl. No.: 11/661,474

(22) PCT Filed: Aug. 26, 2005
(86) PCT No.: PCT/US05/30356

§ 371 Date: Jun. 19, 2008

Related U.S. Application Data
(60) Provisional application No. 60/604,728, filed on Aug. 26, 2004.

(51) Int. Cl. H01L 21/00

(52) U.S. Cl. 219/69.14

(57) ABSTRACT

An apparatus for nano-scale electric discharge machining of a conductive workpiece. In one embodiment, the apparatus includes a dielectric medium deposited on a surface of the workpiece to form a dielectric layer having a thickness, a positioning device capable of moving in three dimensions, an electrode having a nano-scaled tip and mounted to the positioning device, a power source electrically coupled with the electrode and the workpiece, and a controller in communication with the positioning device for generating a signal to cause the nano-scaled tip of the electrode to move to a desired position over the surface of the workpiece. In operation a biasing voltage over a threshold voltage is applied from the power source between the nano-scaled tip of the electrode and the surface of the workpiece such that an avalanche current is formed across the nano-scaled tip of the electrode and the surface of the workpiece to perform machining of the workpiece.

### CROSS-REFERENCE TO RELATED PATENT APPLICATION

This application claims the benefit, pursuant to 35 U.S.C. § 119(e), of provisional U.S. patent application Ser. No. 60/604,728, filed Aug. 26, 2004, entitled “Method, System And Apparatus For Nano-scale Electric Discharge Machining,” by Ajay P. Malshe, Kumar R. Virwani and Kamlakar P. Rajurkar, which is incorporated herein by reference in its entirety.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference. In terms of notation, hereinafter, “[n]” represents the nth reference cited in the reference list. For example, [7] represents the 7th reference cited in the reference list, namely, K. R. Virwani, A. P. Malshe, W. F. Schmidt, D. K. Sood, “Mechanical Strength Measurements of Silicon Nano-structures Using Scanning Probe System: An NDE Approach”, Smart Materials and Structures, 12, 1028-1032 (2003).

### STATEMENT OF FEDERALLY-SPONSORED RESEARCH

The present invention was made with Government support under a contract No. EPS-9977830 awarded by National Science Foundation. The United States Government may have certain rights to this invention pursuant to this grant.

This application is being filed as PCT International Patent application in the name of Board of Trustees of the University of Arkansas and the University of Nebraska, both U.S. national corporations, Applicants for all countries except the U.S., and Ajay P. Malshe, Kumar R. Virwani, citizens of India, and Kamalakar P. Rajurkar, a citizen of the United States of America, Applicants for the designation of the U.S. only, on 26 Aug. 2005.

Some references, which may include patents, patent applications and various publications, are cited in a reference list and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference. In terms of notation, hereinafter, “[n]” represents the nth reference cited in the reference list. For example, [6] represents the 6th reference cited in the reference list, namely, Chad, K. R. Virwani, A. P. Malshe, and W. F. Schmidt, “Design Consideration, Process And Mechanical Modeling, And Tolerance Analysis Of A MEMS-Based Mechanical Machining System-On-A-Chip For Nano Manufacturing”, O'Neal IMECE 2002.

### FIELD OF THE INVENTION

The present invention generally relates to nano-scale electric discharge machining, and in particular to the utilization of a scanning tunneling microscope platform to perform nano-scale electric discharge machining of a workpiece.

### BACKGROUND OF THE INVENTION

Nano-scale (<100 nm) machined structures such as vias, cavities, channels, etc. are essential for fabrication of nano-integrated systems [1]. Applications include Z-axis blind and through nano vias for interconnects [2], nano jets for next generation atomizers for micro fuel cells [3], single DNA (Deoxyribonucleic Acid) detection devices [1], and molecular sieves for protein sorting [3]. One of the challenges is to nano-machine a diverse set of materials, for example from gold metallized polymers for electronic applications to difficult-to-cut titanium alloy for biomedical applications, at low cost and high speed. Thus development of material-specific nano machining processes at low cost and high speed is essential. An extensive effort has been reported in the literature for techniques for machining at nano-scale. A brief summary of some of the efforts is given in the Table 1. These processes have potential for specific application. However, it is still needed to develop a process, which can generate precise nano features and structures in hard and difficulty-to-cut materials in a less controlled environment, at low cost. In the light of these requirements, electric discharge machining (hereinafter “EDM”) in which the material removal is implemented by electric discharges in a dielectric medium may offer an attractive alternative.

EDM is a well known process for forming features, such as holes, slots and notches of various shapes and configurations, in an electrically conductive workpiece. An EDM [26] typically employs an electrode having the desired shape that is advanced toward a workpiece to be machined. A suitable power supply is applied to create an electric potential between the electrode and the workpiece for forming a controlled spark which melts and vaporizes the workpiece material to form the desired feature. The cutting pattern of the electrode is usually computer numerically controlled (hereinafter “CNC”) [27] whereby servo-motors control the relative positions of the electrode and the workpiece. During machining, the electrode and the workpiece are immersed in a dielectric fluid, which provides insulation against premature spark discharge, cools the machined area, and flushes away the removed material.

TABLE 1
Comparison of nano-machining techniques.

| | Minimum 3D | Contamination/ | | | |
|---|---|---|---|---|---|
| Nano Machining | Feature Size and | Redeposition/ | Speed of | | |
| Processes | Materials | Pileup | Machining | Scalability | Cost |
| Scanning Probe Microscope | 20 nm+; | Pileup | Fast | Yes | Low |
| (SPM) Based Indentation | all types of | | | | |
| and Mechanical Machining | materials | | | | |
| [4-7] | | | | | |
| Nano-imprinting [8-9] | 10 nm; | Residue buildup/ | Fast | Yes | Low in |
| | polymers and | contamination | | | volume |
| | silicon | | | | |
| Focused Ion Beam (FIB) | 30 nm; | Ga⁺ ion | Slow | No | High |
| [10-11] | all types of | implantation/ | | | |
| | materials | material | | | |
| | | redeposition | | | |
| Femtosecond laser [12-13] | 100 nm; | Laser redeposition | Fast | Yes | High |
| | all materials | | | | |
| UV Lithography [14-15] | 90 nm; | Photoresist/ | Slow | Yes | High |
| | polymers and | development | | | |
| | semiconductors | residue | | | |
| Electron Beam Lithography | 5 nm; | No | Slow | No | High |
| (EBL) [16-17] | all types of | | | | |
| | materials | | | | |
| X-ray Lithography [18-19] | 1 nm; | No | Slow | No | High |
| | all types of | | | | |
| | materials | | | | |

Recently, the EDM process has been extended to micro-scale machining. A variety of microstructures, such as, three dimensional (hereinafter “3D”) micro cavities, circular, triangular, square, and/or pentagonal blinds and the through holes, has been machined using the EDM technology [20-25].

Since 1981[28] nanoscience and nanotechnology have been greatly influenced by the invention of the scanning tunneling microscope (hereinafter “STM”), for which Heinrich Rohrer and Gerd K. Binnig received the Nobel Prize in Physics in 1986. This remarkable device detects small currents that pass between an STM tip and a sample being observed, allowing ones to “see” substances at the scale of individual atoms. The operation of an STM is a unique combination of quantum mechanics, physics, mechanical design and electronic control [29-31]. In an STM, a tip and a sample made from conducting materials are separated by a very small gap, for example, in a range of from 1 nm to 10 nm. The tip is held at ground voltage while the sample is positively biased. A typical bias voltage is about 200 mV-500 mV. Electrons pass through the barrier between the tip and the sample by a quantum mechanical process called tunneling producing a current [32]. This tunneling current forms a basis of imaging in a typical STM. The tunneling current depends exponentially on the distance between the tip and the sample. This gives the STM its remarkable resolution in the Z (or vertical) direction.

The typical use of an STM is to scan atomically flat surfaces of conducting materials to obtain topographical images of the surfaces. Other applications of the STM have also been reported. For example, the STM may be used to push individual atoms around on a surface to build rings and wires that are only one atom wide [43]. Other processes like mechanical indentation of materials, field assisted evaporation, and chemical reaction processes may also be performed using STM. However, no apparatus and method for fabricating and machining a variety of nano-scaled structures in relation to STM has been developed.

Therefore, a heretofore unaddressed need exists in the art to address the aforementioned deficiencies and inadequacies.

### SUMMARY OF THE INVENTION

In one aspect, the present invention relates to an apparatus for nano-scale electric discharge machining of a conductive workpiece. In one embodiment, the apparatus includes a dielectric medium deposited on a surface of the workpiece to form a dielectric layer having a thickness, T, a positioning device capable of moving in three dimensions, and an electrode having a nano-scaled tip and mounted to the positioning device, where in operation the nano-scaled tip can be positioned over the surface of the workpiece to define a distance, D, therebetween the nano-scaled tip and the surface of the workpiece. The apparatus also includes a power source electrically coupled with the electrode and the workpiece, and a controller in communication with the positioning device for generating a signal to cause the nano-scaled tip of the electrode to move to a desired position over the surface of the workpiece.

In operation, a biasing voltage over a threshold voltage is applied from the power source between the nano-scaled tip of the electrode and the surface of the workpiece such that an avalanche current is formed across the nano-scaled tip of the electrode and the surface of the workpiece to perform machining, or scanning of the workpiece. The avalanche current comprises electrons forming a column of plasma between the nano-scaled tip of the electrode and the surface of the workpiece, and the avalanche current is a function of the distance D between the nano-scaled tip of the electrode and the surface of the workpiece and the applied biasing voltage over a threshold voltage. In one embodiment, at least the avalanche current causes a nano-scale dimple formed on the surface of the workpiece, and the material corresponding to the nano-scale dimple is removed by the dielectric fluid. In another embodiment, the avalanche current can be utilized to scan at least the surface of the workpiece.

In one embodiment, the apparatus further includes an ampere meter that is electrically connected to the electrode and the workpiece for detecting the avalanche current. The detected avalanche current is feedback to the controller for determining and monitoring the distance D. Moreover, the apparatus includes a display in communication with the controller for displaying a surface structure of the workpiece reconstructed from the detected avalanche current, or a surface structure of the workpiece from scanning. Additionally, the apparatus includes means for flushing the dielectric medium.

The dielectric medium is characterized by dielectric strength and the threshold voltage is no smaller than the dielectric strength. The dielectric medium can be in a form of fluid, or in a form of solid. For example, in one embodiment, the dielectric medium includes a dielectric fluid having a dielectric constant not smaller than 5. In one embodiment, the dielectric medium comprises an electric discharge machining oil. In one embodiment, T≧D.

The power source includes a DC power source, a pulsed DC and AC power source, or a combined DC, pulsed DC and AC power source. In one embodiment, the biasing voltage between the nano-scaled tip of the electrode and the surface of the workpiece is adjustable in a range of 10 mV to 100 V, preferably in a range of 300 mV to 30 V, and the frequency of the biasing voltage is adjustable in a range of 0.01 micro Hz to 30 MHz.

In one embodiment, the positioning device has piezoelectric actuators, P_{X}, P_{Y} and P_{Z}, adapted for moving the electrode along X, Y and Z directions, respectively, where the X, Y and Z directions are perpendicular to each other with the X and Y directions defining an X-Y plane parallel to the surface of the workpiece and the Z direction perpendicular to the surface of the workpiece. In one embodiment, the positioning device is controllable by the controller to operate in a constant-height mode in which the position of the nano-scaled tip of the electrode is substantially maintained within the X-Y plane during operation. In another embodiment, the positioning device is controllable by the controller to operate in a constant-current mode in which the avalanche current is maintained at a substantially constant level during operation.

The nano-scaled tip of the electrode is made of a material that is mechanically, chemically, electrically and biomedically compatible with the workpiece. In one embodiment, the material comprises platinum-iridium (Pt—Ir) or tungsten, which is etched electrochemically, machined/deposited with focuses ion beams to nanosize.

In another aspect, the present invention relates to a method for nano-scale electric discharge machining of a conductive workpiece. In one embodiment, the method comprises the steps of depositing a dielectric medium on a surface of the workpiece to form a dielectric layer having a thickness, T, positioning an electrode with a nano-scaled tip over the surface of the workpiece at a desired position, and applying a biasing voltage over a threshold voltage between the nano-scaled tip of the electrode and the surface of the workpiece such that an avalanche current is formed across the nano-scaled tip of the electrode and the surface of the workpiece to perform machining, or scanning of the workpiece. Scanning of the surface of the workpiece may be performed before and/or after the machining operation.

In one embodiment, the method further comprises the steps of detecting the avalanche current, and adjusting the position of the nano-scaled tip of the electrode according to the detected tunneling current. Additionally, the method comprises the steps of reconstructing a surface structure of the workpiece from the detected avalanche current, and displaying the surface structure of the workpiece. Moreover, the method comprises the step of adjusting the biasing voltage in a range of 10 mV to 100 V, preferably in a range of 300 mV to 30 V, and the frequency of the biasing voltage is adjustable in a range of 0.01 micro Hz to 30 MHz. In one embodiment, the biasing voltage is provided by a DC power source, a pulsed DC and AC power source, or a combined DC, pulsed DC and AC power source. Furthermore, the method comprises the step of flushing the dielectric medium during and/or after machining of the workpiece.

The positioning step, in one embodiment, is performed by piezoelectric actuators, P_{X}, P_{Y} and P_{Z}, where each piezoelectric actuator is engaging with the electrode, respectively.

In one embodiment, the applying step is operated in a constant-height mode, where when the nano-scaled tip of the electrode scans the surface of the workpiece, the position of the nano-scaled tip of the electrode is maintained substantially within an X-Y plane that is substantially parallel to the surface of the workpiece during operation. In another embodiment, the applying step is operated in a constant-current mode, where the avalanche current is maintained at a substantially constant level during operation.

In yet another aspect, the present invention relates to an apparatus for nano-scale electric discharge machining of a conductive workpiece. In one embodiment, the apparatus includes a dielectric medium deposited on a surface of the workpiece to form a dielectric layer having a thickness, and a plurality of electrodes, E₁, E₂, . . . and E_{N}, each electrode E_{I} having at least one nano-scaled tip, I=1, . . . , N, N being an integer greater than one. The apparatus also includes means for moving the plurality of electrodes individually or in coordination so as to position each electrode E_{I} over a surface of the workpiece at a desired position, and means for applying a biasing voltage over a threshold voltage between a corresponding electrode E_{I} and the surface of the workpiece, respectively, such that an avalanche current is formed across the nano-scaled tip of at least one of the plurality of electrodes and the surface of the workpiece to perform machining, or scanning of the workpiece.

In one embodiment, the apparatus further includes means for measuring an avalanche current corresponding to each electrode E_{I} and the surface of the workpiece, respectively, and a controller in communication with the moving means, the applying means and the measuring means for processing data received from the moving means, the applying means and the measuring means so as to generate at least one control signal in response. Additionally, the apparatus includes a display for displaying a surface structure of the workpiece reconstructed from the measured avalanche current. Furthermore, the apparatus includes means for flushing the dielectric medium.

The measuring means, in one embodiment, has an ampere meter having a plurality of measuring channels, each measuring channel electrically coupled to one of the plurality of the electrodes E₁, E₂, . . . and E_{N} and the workpiece for detecting a corresponding avalanche current.

In one embodiment, the moving means has a plurality of piezoelectric actuators, P₁, P₂, . . . and P_{M}, wherein each piezoelectric actuator P_{J} engages with a corresponding electrode E_{I} and capable of moving, the corresponding electrode E_{I} along X, Y and Z directions, respectively, where J=1, . . . , M, M is an integer and the total number of plurality of piezoelectric actuators, wherein the X, Y and Z directions are perpendicular to each other with the X and Y directions defining an X-Y plane parallel to the surface of the workpiece and the Z direction perpendicular to the surface of the workpiece. In one embodiment, M=N.

In a further aspect, the present invention relates to an apparatus for nano-scale electric discharge machining of a conductive workpiece. In one embodiment, the apparatus has an electrode having a working end with a plurality of nano-scaled tips, where the plurality of nano-scaled tips are aligned at staggered length, and a power source electrically coupled to the electrode and the workpiece for biasing a voltage between the electrode and the workpiece. The plurality of nano-scaled tips of the electrode, in one embodiment, are spatially arranged in an array. The difference in length from one tip to its neighbor tip of the nano-scaled tips of the electrode is variable.

The apparatus further has means for moving the electrode to a desired position. In one embodiment, the moving means includes a controller for generating a signal representative of a distance in a direction, and a piezoelectric actuator mounted to the electrode for operably moving the electrode the distance in the direction in responsive to the signal received from the controller, where the direction corresponds to a direction perpendicular to the surface of the workpiece, a direction parallel to the surface of the workpiece, or a combination thereof. Moreover, the apparatus has means for measuring the avalanche current across the electrode and the workpiece.

In operation a biasing voltage over a threshold voltage is generated from the power source between the longest nano-scaled tip of the electrode and the surface of the workpiece such that an avalanche current is formed across the longest nano-scaled tip of the electrode and the surface of the workpiece to perform machining of the workpiece, and wherein as the machining of the workpiece progresses and when the longest nano-scaled tip of the electrode is eroded, a next longest nano-scaled tip of the electrode is brought close to the surface of the workpiece to establish a new avalanche current to continue the machining of the workpiece.

In yet a further aspect, the present invention relates to a method for nano-scale electric discharge machining. In one embodiment, the method includes the steps of (a) positioning an electrode having a working end with a plurality of nano-scaled tips over a surface of a workpiece, where the plurality of nano-scaled tips are aligned at staggered length, (b) applying a biasing voltage over a threshold voltage between the electrode and the surface of the workpiece such that an avalanche current is formed across the longest of the plurality of nano-scaled tips and the surface of the workpiece to perform machining of the workpiece, (c) moving a next longest nano-scaled tip of the electrode closer to the surface of the workpiece when the longest nano-scaled tip of the electrode is eroded, and (d) repeating steps (b) and (c) until the workpiece is machined. In one embodiment, the plurality of nano-scaled tips of the electrode are spatially arranged in an array.

In another aspect, the present invention relates to a method for nano-scale electric discharge interacting with a workpiece. In one embodiment, the method includes the step of forming an avalanche current across a nano-scaled tip of an electrode and a surface of a workpiece to interact with the workpiece. The interacting can be in several modes. For example, one is a machining mode in which machining is performed by the formed avalanche current. Another exemplary mode is a scanning mode in which scanning is performed by the formed avalanche current. An additional exemplary mode is a combination of a machining mode and a scanning mode.

In yet another aspect, the present invention relates to an apparatus for nano-scale electric discharge interacting with a workpiece. In one embodiment, the apparatus has a nano-scaled tip associated with an electrode to form an avalanche current across the nano-scaled tip and a surface of the workpiece to interact with the workpiece. When the present invention is practiced in a scanning mode, the constant-height mode as set forth above is preferably utilized. When the present invention is practiced in a machining mode, the constant-current mode as set for is preferably utilized.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

FIG. 1A schematically shows an apparatus for nano-scale electric discharge machining according to one embodiment of the present invention.

FIG. 1B schematically shows the apparatus of FIG. 1A operating at a constant-height mode.

FIG. 1C schematically shows the apparatus of FIG. 1A operating at a constant-current mode.

FIG. 2A schematically shows an electrode having a plurality of nano-scaled tips aligned at staggered length according to one embodiment of the present invention.

FIG. 2B shows an image of an electrode having a plurality of nano-scaled tips aligned at staggered length according to one embodiment of the present invention. The inset shows an enlarged image of one of the plurality of nano-scaled tips.

FIG. 3 shows a perspective view of an optical micrograph of an electrode-workpiece interface in a dielectric medium according to one embodiment of the present invention.

FIG. 4A shows an STM image of an atomically flat gold surface submerged in a EDM oil before nano-EDM machining.

FIG. 4B shows an STM image of the atomically flat gold surface submerged in the EDM oil, as shown in FIG. 4A, after nano-EDM machining according to one embodiment of the present invention.

FIG. 4C shows a section analysis of the machined structures shown in FIG. 4B.

FIG. 4D shows a bearing analysis of the machined structures shown in FIG. 4B.

FIG. 5 shows a volume of material removal in a nano-EDM of a workpiece versus machining time according to one embodiment of the present invention.

FIG. 6 shows a section analysis of an STM image of a nano-EDM machined Au(111) terrace according to one embodiment of the present invention.

FIG. 7 shows a section analysis of another S™ image of a nano-EDM machined Au(111) terrace according to one embodiment of the present invention.

### DETAILED DESCRIPTION OF THE INVENTION

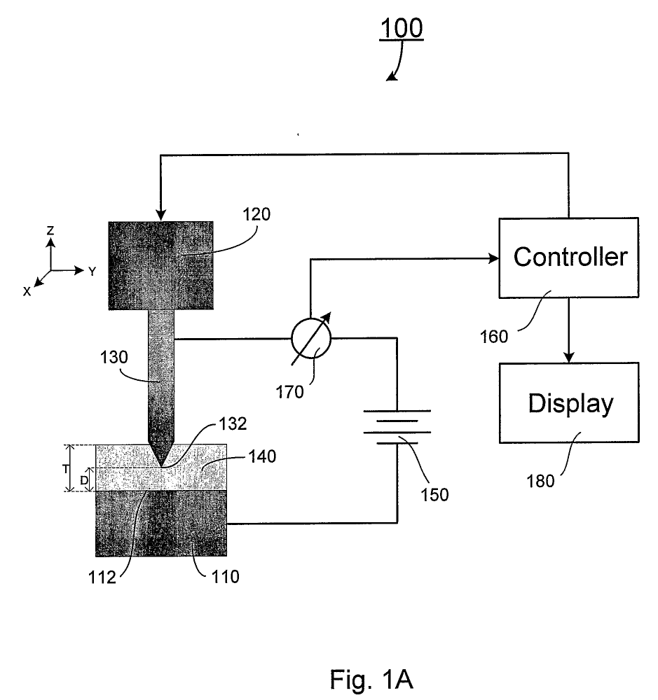

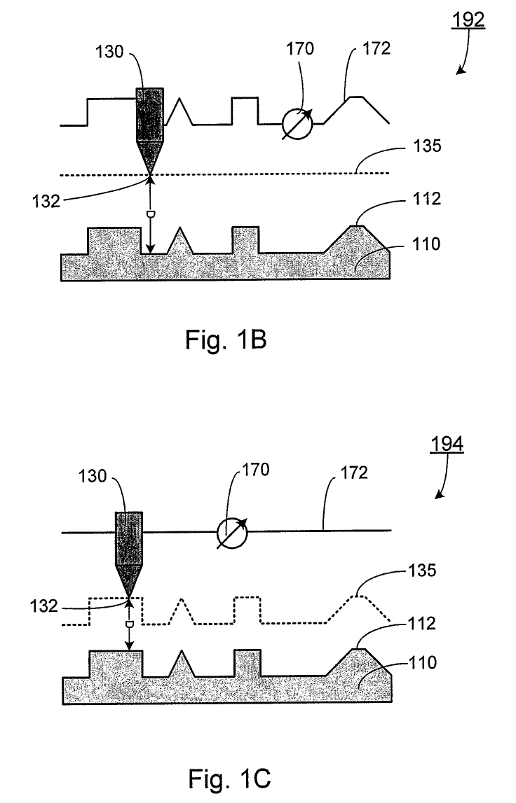

The present invention is more particularly described in the following examples that are intended as illustrative only since numerous modifications and variations therein will be apparent to those skilled in the art. Various embodiments of the invention are now described in detail. Referring to the drawings FIGS. 1-5, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention. Additionally, some terms used in this specification are more specifically defined below.

### DEFINITIONS

The terms used in this specification generally have their ordinary meanings in the art, within the context of the invention, and in the specific context where each term is used.

Certain terms that are used to describe the invention are discussed below, or elsewhere in the specification, to provide additional guidance to the practitioner in describing the apparatus and methods of the invention and how to make and use them. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only, and in no way limits the scope and meaning of the invention or of any exemplified term. Likewise, the invention is not limited to various embodiments given in this specification. Furthermore, subtitles may be used to help a reader of the specification to read through the specification, which the usage of subtitles, however, has no influence on the scope of the invention.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “dielectric medium” refers to a substance that is highly resistant to a flow of an electric current. The dielectric medium is characterized by dielectric strength and a dielectric constant. For a given configuration of a dielectric medium and electrodes, the dielectric strength of the dielectric medium corresponds to the minimum electric field applied to the electrodes that produces breakdown of the dielectric medium. The field strength at which breakdown occurs in a given configuration is dependent on the respective geometries of the dielectric medium and the electrodes with which the electric field is applied, as well as the rate of increase at which the electric field is applied. The dielectric constant is defined as a ratio of the static permittivity of the dielectric medium to the vacuum permittivity, i.e., the ratio of the amount of electric energy stored in the dielectric medium, when a static electric field is imposed across it, relative to vacuum that has a dielectric constant of 1. Electrically, the dielectric constant is a measure of the extent to which a substance concentrates the electrostatic lines of flux. The dielectric medium can be in a form of fluid, or in a form of solid.

As used herein, the term “workpiece” refers generally to a chip or substrate upon which a nano-scaled pattern (structure) is constructed by means of a nano-EDM tool. A workpiece includes at least one material that is a conductor and/or semiconductor, for example, atomically flat gold metallization with or without a polymer substrate, titanium alloy in highly doped silicon nitride (Si₃N₄) and/or silicon di-oxide (SiO₂) membranes. These materials are identified for nano-electronic packaging, biomedical implants, and a single DNA detection device. However, those skilled in the art will appreciate that a variety of other types of materials are suitable.

### Overview of the Invention

The present invention, in one aspect, relates to an apparatus for nano-scale electric discharge machining (hereinafter “nano-EDM”) of a conductive workpiece. Referring to FIGS. 1A-1C and first to FIG. 1A, in one embodiment, the apparatus 100 includes a dielectric medium 140 deposited on a surface 112 of the workpiece 110 to form a dielectric layer 140 having a thickness, T, a positioning device 120 capable of moving in three dimensions, and an electrode 130 having a nano-scaled tip 132 and mounted to the positioning device 120, where in operation the nano-scaled tip 132 can be positioned over the surface 112 of the workpiece 110 to define a distance, D, therebetween the nano-scaled tip 132 and the surface 112 of the workpiece 110. Furthermore, the apparatus 100 includes a power source 150 electrically coupled with the electrode 130 and the workpiece 110, and a controller 160 in communication with the positioning device 120 for generating a signal to cause the nano-scaled tip 132 of the electrode 130 to move to a desired position over the surface 112 of the workpiece 110.

In operation, a biasing voltage over a threshold voltage is applied from the power source 150 between the nano-scaled tip 132 of the electrode 130 and the surface 112 of the workpiece 110 such that an avalanche current is formed across the nano-scaled tip 132 of the electrode 130 and the surface 112 of the workpiece 110 to perform machining of the workpiece 110. The avalanche current has electrons forming a column of plasma between the nano-scaled tip 132 of the electrode 130 and the surface 112 of the workpiece 110, and the avalanche current is a function of the distance D between the nano-scaled tip 132 of the electrode 130 and the surface 112 of the workpiece, and the applied voltage.

Theoretically, a tunneling probability for the electrons tunneling through the gap between the nano-scaled tip 132 of the electrode 130 and the surface 112 of the conductive workpiece 110 in the dielectric medium 140 that is characterized by a dielectric strength and a dielectric constant is given by the following equation [54]:

$$T ( V ) \approx {[ 4 k \frac{δ}{( 1 + k {δ}^{2} )} ]}^{2} exp ( 2 \frac{D}{δ} ) \approx exp ( - D \sqrt{\frac{2 m Φ}{ℏ}} ) , \\ where \\ {k}^{2} = 2 \frac{mV}{{ℏ}^{2}} and {( k δ )}^{2} = V ( {U}_{0} - V ) = ( \frac{V}{Φ} ) , \qquad ( 1 )$$

T(V) is a transmission coefficient of the electrons tunneling through the gap between the nano-scaled tip 132 of the electrode 130 and the surface 112 of the workpiece 110, D is the distance of the gap between the nano-scaled tip 132 of the electrode 130 and the surface 112 of the workpiece 110, Φ is an effective work function that the tunneling electrons experience, which is dependent on the nano-scaled tip 132 of the electrode 130, the surface 112 of the workpiece 110, and the dielectric medium 140 deposited in the gap between the nano-scaled tip 132 of the electrode 130 and the surface 112 of the workpiece 110, V is an external bias applied across the nano-scaled tip 132 of the electrode 130 and the surface 112 of the workpiece 110, m is mass of an electron, and h is the Planck's constant.

The tunneling current, Iₜ, is proportional to the square of the tunneling probability T(V), that is:

Iₜ∝T(V)² (2)

which is a function of the distance D and the effective work function Φ. The tunneling current Iₜ is used to control the position of the nano-scaled tip 132 of the electrode 130 so as to monitor the distance D between the nano-scaled tip 132 of the electrode 130 and the surface 112 of the workpiece 110. In one embodiment, the tunneling current Iₜ is maintained constant during machining.

The energy density, Wₑ, between in the gap the nano-scaled tip 132 of the electrode 130 and the surface 112 of the workpiece 110 is estimated from the Maxwell's equations. The electric field varies across the nano-scaled tip 132 of the electrode 130, and therefore, the net energy density Wₑ is determined by integrating the volume of the electric field under the nano-scaled tip 132 of the electrode 130.

By transforming the system to the cylindrical coordinates, the variation of the electric field, E(Z), in the Z direction is given by

E(Z)=Kr² (3)

where the constant K depends on the applied voltage V. The energy density Wₑ under the nano-scaled tip 132 of the electrode 130 has the form of:

$${W}_{e} = {K}^{2} \frac{∈}{2} \int \int \int {E}^{2} ( z ) d v , \qquad ( 4 )$$

where ∈ is the dielectric constant of the dielectric medium 140. In one embodiment, the nano-scaled tip 132 of the electrode 130 has a parabolic symmetry. It is convenient to rewrite the integral (4) in the cylindrical coordinates, which is:

$${W}_{e} = {K}^{2} \frac{∈}{2} \int \int \int {r}^{4} d r d φ r d . \qquad ( 5 )$$

As a result, the electric field density Wₑ is given by

$${W}_{e} = {K}^{2} \frac{∈}{2} {r}^{5} φ L . \qquad ( 6 )$$

In one embodiment of the present invention, the nano-scaled tip 132 of the electrode 130 has an end radius of about 15 nm, the distance D of the gap between the nano-scaled tip 132 of the electrode 130 and the surface 112 of the workpiece 110 is about 5 nm, and the biasing voltage across the gap is about 10 V. The energy density Wₑ in the gap is approximately 17.7 MJ/m³ in this embodiment. Note that successful practicing of the present invention does not depend on whether the theory presented herein is right.

As shown in equation (6), the energy density Wₑ across the gap between the nano-scaled tip 132 of the electrode 130 and the surface 112 of the workpiece 110 is directly proportional to the dielectric constant of the dielectric medium 140 between the nano-scaled tip 132 of the electrode 130 and the surface 112 of the workpiece 110. The selection of a dielectric medium filled in the gap between the nano-scaled tip 132 of the electrode 130 and the surface 112 of the workpiece 110 is governed primarily by the dielectric constant of the dielectric fluid. The higher the dielectric constant of the dielectric medium is, the higher the energy density is, and thus the better the machining characteristics is. Preferably, a dielectric fluid having a high dielectric constant is used to practice the present invention. In one embodiment, the dielectric medium 140 includes an electric discharge machining oil, for example, Commonwealth Oil: EDM 185 (Commonwealth Oil Corp., Harrow, Ontario NOR 1G0, Canada). Other dielectric media, such as mineral oil, de-ionized water, etc., can also be utilized to practice the present invention.

Furthermore, the process of the nano-EDM is an electro-thermal machining process. The dielectric medium (fluid) 140 filled in the gap between the surface 112 of the workpiece 110 and the nano-scaled tip 132 of the electrode 130 not only acts as a dielectric medium but also helps to carry away the heat and the particulate matter generated as a result of the machining operation. In one embodiment, the workpiece 110 and the nano-scaled tip 132 of the electrode 130 are submerged in the dielectric fluid 140 such that the thickness T of the dielectric fluid on the surface 112 of the workpiece 110 is greater than the distance D between the nano-scaled tip 132 of the electrode 130 and the surface 112 of the workpiece 110, i.e., T≧D, as shown in FIG. 1A. In one embodiment, the dielectric fluid level is maintained at about 0.5-1 mm above the surface 112 of the workpiece 110.

At the nano-scaled tip 132 of the electrode 130 the electric field strength is expressed as

$$E = \frac{V}{D} . \qquad ( 7 )$$

In a typically STM setup, a distance D of a gap between an electrode tip and a surface of a workpiece is about 5 nm. For an STM imaging scan in which a bias voltage of about 300 mV is applied, the electric field strength E across the gap is about 6×10⁷ V/m. For a nano-EDM using a bias voltage of about 10 V, the electric field strength E across the gap is about 2×10⁹ V/m. Comparing with the field strength E in macro and micro EDMs, which is in a range of 10⁶ V/m to 10⁸ V/m, the STM instrument configuration offers stronger field strengths and a wide spectrum of the electric field for machining various materials, particularly difficult-to-cut materials.

In one embodiment of the present invention, the nano-scaled tip 132 of the electrode 130 is grounded, while the workpiece 110 is biased with a biasing voltage from a DC power source. For a nano-EDM, the biasing voltage between the nano-scaled tip 132 of the electrode 130 and the surface 112 of the workpiece 110, in one embodiment, is adjustable in a range of 10 mV to 100 V, preferably in a range of 300 mV to 30 V. The frequency of the biasing voltage is also adjustable in the range of 0.01 microHz to 30 MHz. For a post nano-EDM evaluation, a biasing voltage as low as about 300 mV may be applied for the STM imaging scan. The gap between the nano-scaled tip 132 of the electrode 130 and the surface 112 of the workpiece 110 is filled with an EDM oil, such as Commonwealth Oil: EDM 185.

When the nano-scaled tip 132 of the electrode 130 is brought close to the surface 112 of the workpiece 110, and a biasing voltage over a threshold voltage is applied across the nano-scaled tip 132 of the electrode 130 and the surface 112 of the workpiece 110, a series of rapidly recurring electric discharges are established across the nano-scaled tip 132 of the electrode 130 and the surface 112 of the workpiece 110, which causes a buildup of an electric field across a path of least resistance between the nano-scaled tip 132 of the electrode 130 and the surface 112 of the workpiece 110 (not shown). The electric field causes the dielectric fluid 140 to breakdown into ionic (charged) fragments. As the number of ionic (charged) particles increases, the insulating properties of the dielectric fluid 140 begin to decrease along the path of least resistance, and a current flow from the workpiece 110 to the electrode 130 is formed. Electrons and ions migrate towards the surface 112 of the workpiece 110 and the nano-scaled tip 132 of the electrode 130, respectively at a high flow of current forming a column of plasma and initiating the melting and even evaporation of the surface 112 of the workpiece 110 and the nano-scaled tip 132 of the electrode 130, respectively. Upon removal of the biasing voltage the column of plasma collapses and a portion of the molten materials is ejected from the workpiece. In one embodiment, the current causes a nano-scale dimple formed on the surface 112 of the workpiece 110. Debris (material removals) remaining in the gap is then flushed away with the dielectric fluid 140 and the machining cycle is repeated with application of the next biasing voltage pulse. In one embodiment, the flush process is performed with a microfludic channeled nanoflushing system.

The electrons passing through the dielectric barrier (gap) between the nano-scaled tip 132 of the electrode 130 and the surface 112 of the workpiece 110 are initialized by a quantum mechanical process called tunneling producing an electrically active medium. A strong biasing voltage results in avalanching of the electrons called avalanche-discharge plasma channel, forming an avalanche current between the nano-scaled tip 132 of the electrode 130 and the surface 112 of the workpiece 110. It is this avalanche current that forms the basis of the nano-EDM. To create an avalanche current between the surface 112 of the workpiece 110 and the nano-scaled tip 132 of the electrode 130 to effectively perform machining of the workpiece, a threshold voltage (a minimum biasing voltage) across the nano-scaled tip 132 of the electrode 130 and the surface 112 of the workpiece 110 is needed to overcome the dielectric strength of the dielectric liquid fluid 140. The threshold voltage is no smaller than the dielectric strength of the dielectric liquid fluid 140.

In one embodiment, the avalanche current is detected by an ampere meter 170 that is electrically connected to the electrode 130 and the workpiece 110. The detected avalanche current is feedback to the controller 160 for determining and monitoring the distance D. From the detected avalanche current, a surface structure of the workpiece 110 is reconstructed. The surface structure of the workpiece 110 is visualized on a display 180. In one embodiment, the controller 160 includes a computer. Other types of processors can also be used to practice the present invention. The display 180 includes a cathode ray tube (CRT) monitor, a liquid crystal display (LCD), or the likes.

To machine the workpiece 110 at a desired pattern, the nano-scaled tip 132 of the electrode 130 needs to be positioned precisely at a predetermined position. In one embodiment, this is implemented by mounting the electrode 130 to the positioning device 120 having piezoelectric actuators, P_{X}, P_{Y} and P_{Z}. The piezoelectric actuators P_{X}, P_{Y} and P_{Z} are adapted for moving the electrode 130 along X, Y and Z directions, respectively, where the X, Y and Z directions are perpendicular to each other with the X and Y directions defining an X-Y plane parallel to the surface 112 of the workpiece 110 and the Z direction perpendicular to the surface 112 of the workpiece 110. In one embodiment, the position precisions of the nano-scaled tip 132 of the electrode 130 in the X, Y and Z directions are achieved in a range of about 2-3 nm, respectively, by the piezoelectric actuators, P_{X}, P_{Y} and P_{Z}. In operation, when the controller 160 generates a signal representative of a distance in a J direction, the piezoelectric actuator P_{J} operably moves the electrode 130 the distance in the J direction in responsive to the signal received from the controller 160, where J=X, Y or Z.

In one embodiment, the positioning device 120 is controllable by the controller 160 to operate in a constant-height mode 192 in which the position 135 of the nano-scaled tip 132 of the electrode 130 is substantially maintained within the X-Y plane, as the nano-scaled tip 132 of the electrode 130 is scanning the surface 112 of the workpiece 110, as shown in FIG. 1B. In this operation mode, the tunneling current 172 varies with the position 135 of the nano-scaled tip 132 of the electrode 130. In another embodiment, the positioning device 120 is controllable by the controller 160 to operate in a constant-current mode 194 in which the avalanche current 172 is maintained at a substantially constant level during operation, as shown in FIG. 1C. In the constant-current mode 194, as the nano-scaled tip 132 of the electrode 130 is scanning the surface 112 of the workpiece 110, the position 135 of the nano-scaled tip 132 of the electrode 130 is maintained at a substantially constant distance normal to the surface 112 of the workpiece 110 such that the avalanche current 172 is held at a substantially constant level. In this embodiment, the avalanche current 172 is feedbacked to the controller 160 for generating a signal associated with the tunneling current 172 to control the piezoelectric actuator P_{Z} during operation. The piezoelectric actuator P_{Z} moves the nano-scaled tip 132 of the electrode 130 away from the surface 112 of the workpiece 110 when the signal increases and the piezoelectric actuator P_{Z} moves the nano-scaled tip 132 of the electrode 130 closer to the surface 112 of the workpiece 110 when the signal decreases. In one embodiment, the avalanche current is maintained at a substantially constant level during operation with built-in software that controls the movement of the nano-scale tip of the electrode.

The workpiece 110 to be machined contains at least one material that is a conductor and/or semiconductor. The material of interest includes gold, titanium alloy, highly doped silicon nitride and silicon di-oxide, and gold-coated polymer for nano-scale machining. The choices of these materials are based upon their immediate need in advanced electronics as well as biomedical applications. Other types of conductive, in particular, difficult-to-cut materials can also be utilized to practice the present invention. One of the practical considerations for the workpiece 110 is to have an atomically flat surface with an average surface roughness smaller than the size of the nano-scaled features to be machined.

The nano-scaled tip 132 of the electrode 130 is made of a material that is mechanically, chemically and biomedically compatible with the workpiece. In one embodiment, the material includes platinum-iridium (Pt—Ir) or tungsten, preferably, Pt—Ir alloy, which is chemically inert to many reactions including oxidation and halogenations. Other materials can also be utilized to practice the present invention.

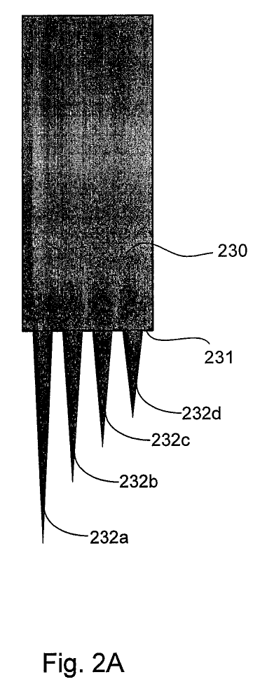

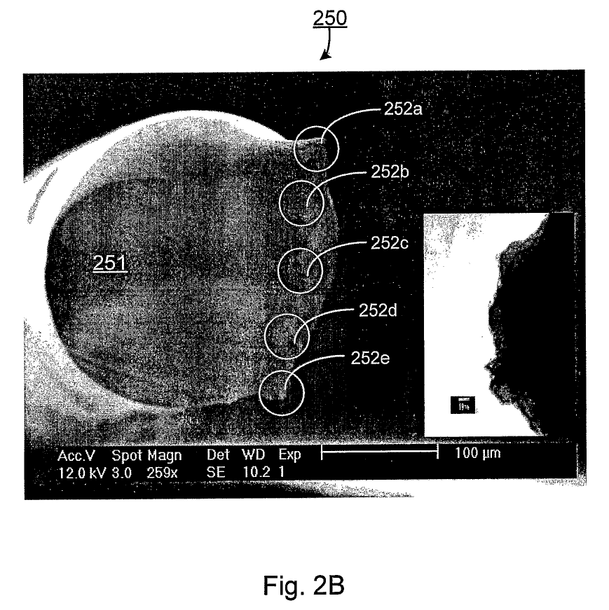

Referring to FIGS. 2A and 2B, and first to FIG. 2A, an electrode 230 having a working end 231 with a plurality of nano-scaled tips 232a-232d is shown according to one embodiment of the present invention. The electrode and a workpiece to be machined are electrically connected by a power source for applying a biasing voltage therebetween. The plurality of nano-scaled tips 232a-232d of the electrode 230 are aligned at staggered length. For example, nano-scaled tip 232a is a longest nano-scaled tip, and nano-scaled tip 232b is a next longest nano-scaled tip, while nano-scaled tip 232d is a shortest nano-scaled tip among the plurality of nano-scaled tips 232a-232d, as shown in FIG. 2A. The difference in length from one tip to its neighbor tip of the nano-scaled tips 232 of the electrode 230 is variable. During operation a biasing voltage over a threshold voltage is applied across the electrode 230 and the surface of the workpiece such that an avalanche current is formed across the longest nano-scaled tip 232a of the electrode 230 and the surface of the workpiece to perform machining of the workpiece. As the machining of the workpiece progresses, the longest nano-scaled tip 232a of the electrode 230 is gradually eroded, then a next longest nano-scaled tip 232b of the electrode 230 is brought close to the surface of the workpiece to keep the avalanche current for the machining of the workpiece. In one embodiment, the avalanche current is about 1 nA.

FIG. 2B shows an electrode 250 that is fabricated by mechanically shearing and then lightly etching a Pt—Ir micro wire 251 with multiple tips 252a-252e. Each of the five tips 252a-252e has a nano-scaled radius. These tips 252a-252e are staggered at various distances from the surface of the workpiece (not shown). In this exemplary embodiment shown in FIG. 2B, these nano-scaled tips 252a-252e of the electrode 250 are spatially arranged in an array. Other spatial arrangements (staggering distributions) of the plurality of nano-scaled tips of the electrode can also be employed to practice the present invention. The staggering configuration of the plurality of nano-scaled tips of the electrode plays an important role in steady machining while providing a long electrode tool life.

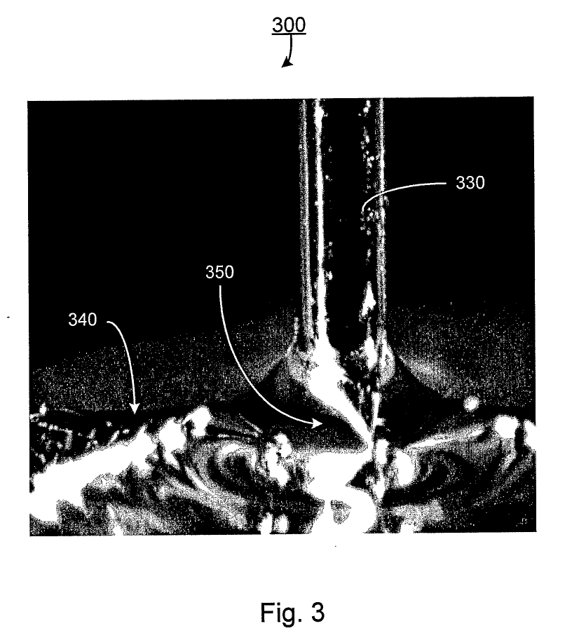

FIG. 3 shows an optical micrograph 300 of a nano-EDM setup having a Pt—Ir electrode 330 with a nano-scaled tip and a EDM oil meniscus 340 submerging a workpiece (not shown) to form an electrode-workpiece interface (gap) 350 in the EDM oil meniscus 340, according to one embodiment of the present invention.

These and other aspects of the present invention are further described below.

### EXAMPLES AND IMPLEMENTATIONS

Without intend to limit the scope of the invention, further exemplary procedures and preliminary experimental results of the same according to the embodiments of the present invention are given below.

In one embodiment, nano-scale electric discharge machining of an atomically flat gold surface of a workpiece was performed using a Pt—Ir electrode having a tip with an end radius about 15-20 nm. The tip of the Pt—Ir electrode and the workpiece electrode were separated by a very small gap (few nanometers) and submerged in an EDM oil, for example, Commonwealth Oil: EDM 185. The nano-EDM instrument operated in a constant-current mode during machining. The atomically flat gold was grown using molecular beam epitaxy (MBE). In one embodiment, a bias voltage of about 10 V was applied across the tip of the Pt—Ir electrode and the workpiece electrode using controls available in the instrument software. An avalanche current was measured to be about 1 nA. The avalanche current was remained at the constant level (about 1 nA) while machining. The precision in controlling avalanche-tunneling current to be constant provides a remarkable precision in machining resolution in the Z-axis (or vertical). The motion of the tip of the Pt—Ir electrode in the X-Y plane is controlled by piezoelectric ceramic actuators. The resolution in the X and Y directions is about 2 nm.

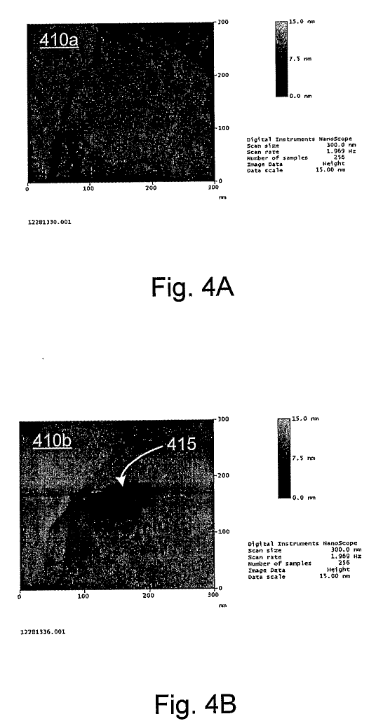

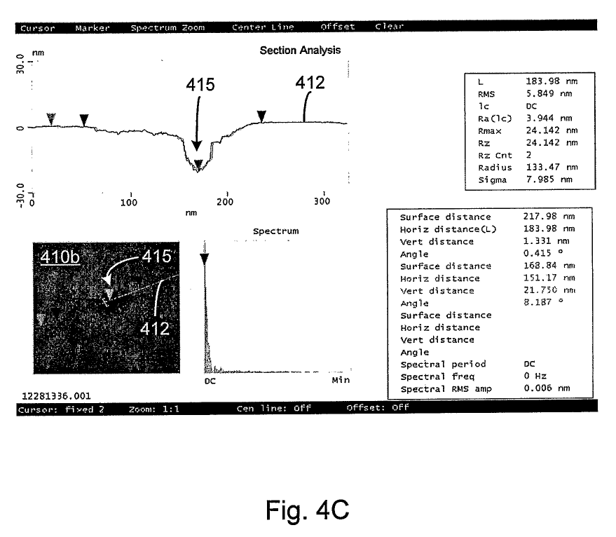

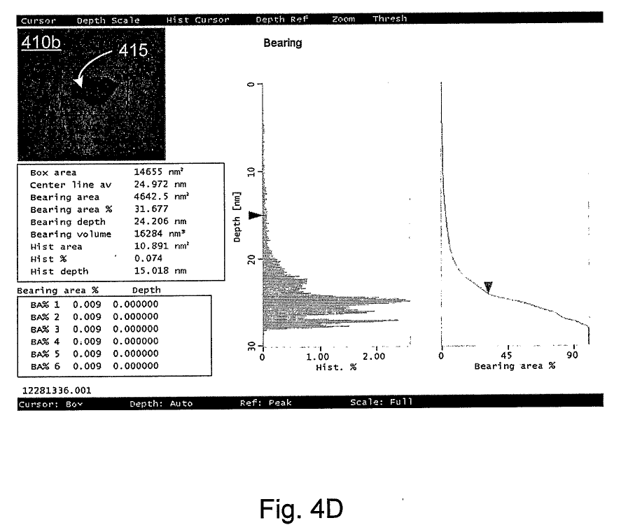

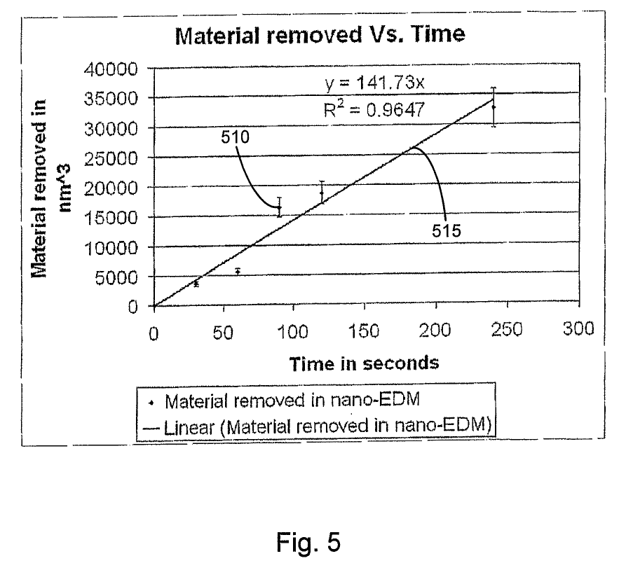

The nano-EDM process resulted in a remarkable formation of different nano-scaled via holes. Sizes of the machined nano-scaled via holes varied with the machining time which corresponds to the pulse time of the biasing voltage applied across the tip of the Pt—Ir electrode and the workpiece electrode. For example, for the pulse time of 30, 60, 90, 120 and 240 seconds, the machined via holes in the atomically flat gold surface of the workpiece have a diameter of 22, 35, 55, 78 and 85 nm, respectively. Referring to FIGS. 4A-4D, STM images of the atomically flat gold surface of the workpiece before and after the nano-EDM process, and section and bearing analyses after the nano-EDM process were shown, respectively, according to one embodiment of the present invention. In this embodiment, the biasing voltage applied across the tip of the Pt—Ir electrode and the workpiece electrode was about 10 V, and the workpiece was machined for about 90 seconds. As shown in FIGS. 4A and 4B, the STM images 410a and 410b were respectively corresponding to a topographical image of the atomically flat gold surface of the workpiece before and after the nano-EDM process, which were obtained by performing scanning according to the present invention. Both STM images 410a and 410b were obtained with a scan size of about 300 nm along the X and Y directions, a scan rate at about 1.969 Hz and a number of samples being about 256. In the STM image 410b, as shown in FIG. 4B, an image portion 415 was corresponding to a machined dimple in the atomically flat gold surface of the workpiece. The machined dimple 415 was further evaluated using the section analysis and the bearing analysis, as shown in FIGS. 4C and 4D, respectively. The section analysis and the bearing analysis, known to people skilled in the art, were adapted for analyzing a cross section profile of the machined dimple 415 along line 412, a volume of the removed material of the machined dimple 415 in terms of the bearing volume of the machined dimple 415, respectively. In this exemplary embodiment, the bearing volume of the machined dimple 415 was about 16,284 nm³. Furthermore, as shown in FIG. 5, the volume of the removed material 510 estimated by the bearing analysis was directly proportional to the time for which the biasing voltage was applied to the workpiece material, which indicated that the successful nano-EDM writing (machining) was initiated by an electric discharge created plasma forming an avalanche current between the nano-scaled tip of the electrode and electrodes of the surface of the workpiece. The volume of the removed material 510 was fitted with a linear fitting line 515, as shown in FIG. 5.

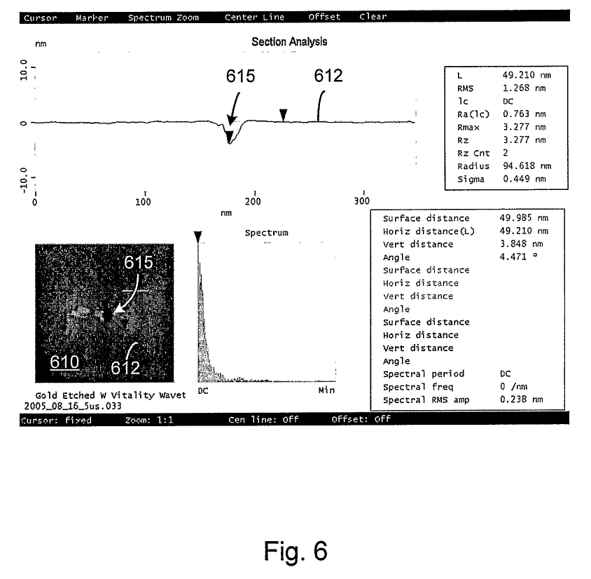

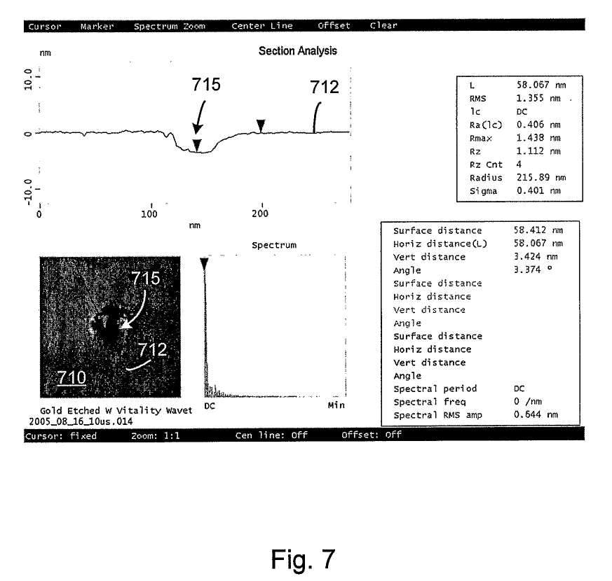

Referring to FIGS. 6 and 7, section analyses of a nano-scale electric discharge machined Au(111) terrace were shown according to another embodiment of the present invention. In the embodiment, an etched W tip electrode was used as a tool electrode to perform the nano-EDM. The etched W tip electrode was positioned over a surface of a Au(111) terrace to be machined, thereby forming a 20 nm discharge gap therebetween. Vitality EDM oil from Commonwealth Oil was deposited on the surface of the Au(111) terraces to act as an dielectric medium in the discharge gap. Square pulses with 50% duty cycle having a voltage of about 16 V were applied across the discharge gap, which resulted in a dimple 615 (715) shown in FIG. 6 (FIG. 7) machined on the Au(111) terrace. The pulse times of the biasing voltage applied for machining dimples 615 and 715 were about 5 μs and 10 μs, respectively. A cross section profile of such a machined dimple 615 (715) and 715 along line 612 (712) was shown in FIG. 6 (FIG. 7).

When the apparatus operated in a typical STM imaging condition in which the biasing voltage was less than about 350 mV in the same dielectric liquid medium, no electro-mechanical writing (machining) was observed. Thus, to perform machining of a workpiece, a minimum biasing voltage (a threshold voltage) between the nano-scaled tip of the electrode and the electrodes of the surface of the workpiece was essential to overcome the dielectric strength of the dielectric liquid medium. When the biasing voltage was greater than the threshold voltage, an avalanche of the electrons passing through the nano-sized gap between the nano-scaled tip of the electrode and the surface of the workpiece was generated by a quantum mechanical process called avalanche-tunneling producing breakdown of the dielectric medium. This breakdown results into melting of the electrodes, followed by precise material ejection. In one embodiment, the biasing voltage of about 10 V was applied across the nano-scaled tip of the electrode and the surface of the workpiece to perform machining, while the biasing voltage of about 300 mV is used to image the machined region of the workpiece, using the same tip, by the STM.

The performance and potential of the invented nano-EDM process were compared with other existing machining and deposition processes. A literature summary of the comparison was listed in Table 2. It is clear from the literature review that nano-EDM offers one of the best alternatives to generate 2.5D and 3D nano-structures such as vias, blinds and through holes. On the other hand, unlike the other existing machining and deposition processes, the invented nano-EDM process is a non-invasively machining process, where no directly contact of an electrode with a workpiece is required during machining of the workpiece.

TABLE 2
Comparison of different processes for nano-machining

| Type of | Processing Medium | Workpiece | Minium Feature | |
|---|---|---|---|---|
| machining | and mechanism | material | Size | Applications |
| Present Invention: | Dielectric medium, | Any electrically | 20-100 nm | Vias, |
| Nano-EDM | EDM Oil; | conducting or | | Interconnects, |
| | electric discharge | semi-conducting | | nanoscale pores, |
| | plasma channel | materials | | scanning and more |
| | formation | | | |
| Deposition/ | Vacuum; | Nickel, GaAs | 20 nm (Height) | Quantum Dots |
| Removal [33-38] | evaporation | | | |
| Etching [39] | Vacuum; | Organic charge | Few monolayers | Data Storage |
| | thermal evaporation | transfer compound | | |
| Etching [40] | Liquid N₂ temp; | Superconductor | 1-Monolayer | Etching of |
| | electrochemical | YBCO/PBCO | | Superconductors |
| Nano-grafting [41] | Ambient; | N-Vinyl-2- | 1-Monolayer | Grafting of Islands |
| | electrochemical | pyrrolidone on | (0.5-0.6 nm) | |
| | | graphite | | |
| Rubbing [42] | Ambient/Covered by | Polyamide films | Few monolayers | Study of rubbing |
| | liquid crystal; | | | effects |
| | mechanical abrasion | | | |
| Re-construction | Ambient; | Gold | Monolayers | Study of |
| [43] | short range interactions | | | reconstruction |
| | and long range elastic | | | |
| | interactions | | | |
| Etching [44] | Humid Ambient; | Thallium Oxide | <50 nm | Study of etching |
| | electrochemical | | | |
| Anodic Oxidation | NaOH; | Cu | Few monolayers | Oxidation and |
| [45] | electrochemical | | | lithography |
| Etching [46] | Water, Ethanol; | Gold | 3 nm | Lithography |
| | electrochemical | | | |
| Etching [47-48] | Ambient; | Oligosilane | 10 nm | Lithography on |
| | breaking of Oligosilane | | | Gold |
| | film from tip electrons | | | |
| Pitting [49-51] | Ambient; | Graphite | 1-Monolayer | Monolayers |
| | electrochemical | | | removal of material |
| Indentation [52] | Ambient + etching | MoSe₂ | Few monolayers | Lithography |
| | solution; | | | |
| | electrochemical | | | |
| Chemical | Ambient/Humidity; | WₓO₃₋ₓ | N/A | Damage |
| Modification [53] | electrochemical | | | |

TABLE 3
Comparison of operating parameters of macro, micro and nano EDM processes

| | Macro EDM | Micro EDM | Present Invention |
|---|---|---|---|
| Machine | Industrially | Modifications of | Scanning Tunneling |
| | available EDM | industrially available | Microscope platform |
| | | EDM | |
| Electrode material | Copper, Tungsten, | Tungsten, Tungsten | Pt—Ir, Tungsten |
| | Graphite | carbide | |
| Dielectric medium | EDM oil | De-ionized water and | High dielectric constant |
| | | mineral oil | medium, and EDM oil |
| Operating Voltage | 40-400 V | 40-200 V | 300 mV-30 V |
| Current Density | 10³-10⁴ A/mm² | 10³-10⁴ A/mm² | 10³-10⁵ A/mm² |
| Electrode diameter | ~few mms | ~5 μm | 15-25 nm |
| Discharge gap | 0.0127-0.0508 mm | 1-10 μm | 2-10 nm |
| Electric field strength | 10⁷-10⁸ V/m | 10⁷-10⁸ V/m | 10⁶-10⁹ V/m |
| Flushing | Yes | Yes | Optional |
| Electrode Polarity | +/− | +/− | +/− |
| Pulse duration | 0.5 μs-8 ms | ns-ms | ns-ms |
| Total cycle time | μs-ms | ns-ms | ns-ms |

Table 3 shows comparisons of operating parameters for macro, micro and exemplary nano EDM processes, respectively. As shown in Table 3, the operating voltage required for the invented nano-EDM is less than that of the macro EDM and the micro EDM, however the electric field strength and the current density generated for machining are in a range which are an order of magnitude higher than those in the macro EDM and the micro EDM. The most unique feature of the invented nano-EDM is its capability to machine a workpiece at desired nano-scaled patterns and/or structures.

Thus, the present invention, among other unique things, discloses a system and method for nano-scale electric discharge machining of a conductive workpiece at a variety of nano patterns and/or structures.

The present invention can find many applications in a wide spectrum of fields. Among them, some of the applications are given as examples as follows:

Nano and micro packaging: The nano-EDM process can be used to write Z-axis nano-scale vias for electronic and optical interconnections in nano and micro packaging.

Nano-particles and proteins sorting: Nano-particles are very abrasive and dangerous to use. Most commercially available nano-particles have different sizes. It is difficult to sort out all of same size particles. Nano-EDM can be used to machine holes at a specific sub-micron size in a plate of a highly abrasion resistant material. For example, to sort out all particles sized at a diameter of 200 nm, the holes in the plate can be machined at a diameter of 200 μm. Then, different concentration solutions with nano-particles would be placed on either sides of this nano-patterned plate. The difference in solution concentration would cause the nano-particles to be sorted out into at least two categories by its sizes: >200 nm and <200 nm, on either sides of this plate. Depending on the requirements, successive application of this process and apparatus would deliver nano-particles having a diameter of 200 nm (±tolerance on hole size). Furthermore, the application of the nano-EDM can be extended to develop a metallic molecular sieve for sorting nano-particles and proteins. As an extension of the sorting method as described above, biological entities like proteins and DNA can also be sorted by passing those through a nano-scale controlled membrane. Varied size membranes can be used to sort a large number of animal and plant proteins.

Nano-scale channels machining: The nano-EDM process can be employed to machine nano-scale channels in permanent magnetic materials. With the machined channels in such materials it would be possible to achieve magnetic action based motion of the fluid inside the channels doing way with expensive pumping equipment. Nano-channels machined using the nano-EDM method can also be used for DNA micro total analysis and controlling drug delivery.

Modifying the local quality of a catalyst: The nano-EDM method can be used to selectively modify the local quality of a catalyst. In many reactions, all the reactants are not of the same size. Catalysis is a size-dependent property. Thus, the same material can be modified to have various nano-scale perforations, which, in turn, catalyzes the entire chemical reaction to the same rate as opposed to having different reaction rates in the same chemical process.

Sensing sites for different chemicals: Multiple channels created using the nano-EDM could be used as sensing sites for different chemicals. For example, the human nose recognizes various aromas using a lock and key mechanism, the nano-EDM can potentially enable artificial machining of such chemical sensitive sites in various materials.

Quality control: As the interconnect size becomes smaller, the repair of defects at nanometer scale is becoming an increasingly difficult task. The nano-EDM method can be used to machine defects that might be introduced as a result of the fabrication process. The process can be automated to be performed on the production line to monitor the quality of the process.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

### LIST OF REFERENCES

[1] J. Li, D. Stein, C. Mcmullan, D. Branton, M. Aziz, J. A. Golovchenko, “Ion Beam Sculpting at Nanometer Scales” Nature 412, 2001, pp 166-199.
[2] International Technology Roadmap for Semiconductors 1999 Edition.
[3] www.nano.gov.
[4] B. Du, M. R. VanLandingham, Q. Zhang, et al., “Direct measurement of plowing friction and wear of a polymer thin film using the atomic force microscope”, Journal of Materials Research, vol. 16, no. 5, 2001, pp. 1487-1492.
[5] H. W. Schumacher, U. F. Keyser, U. Zeitler, et al., “Nanomachining of mesoscopic electronic devices using an atomic force microscope”, Applied Physics Letters, vol. 75, no. 8, pp. 1107-1109.
[6] Chad, K. R. Virwani, A. P. Malshe, and W. F. Schmidt, “Design Consideration, Process And Mechanical Modeling, And Tolerance Analysis Of A MEMS-Based Mechanical Machining System-On-A-Chip For Nano Manufacturing”, O'Neal IMECE 2002.
[7] K. R. Virwani, A. P. Malshe, W. F. Schmidt, D. K. Sood, “Mechanical Strength Measurements of Silicon Nano-structures Using Scanning Probe System: An NDE Approach”, Smart Materials and Structures, 12, 1028-1032 (2003).
[8] H. Schultz, H. C. Scheer, et al., “New polymer for nanoimprinting”, Journal of Vacuum Science Technology B, 18, 4, 2000, pp. 1861-1865.
[9] J. Wang, X. Y. Sun, L. Chen, S. Y. Chou “Direct Nanoimprint Lithography of Submicron Organic Light-emitting Structures”, Appl. Phys Letters, 75, 18, 1999, pp. 2767-2769.
[10] Olbrich, B. Ebersberger, C. Boit, et al., “High aspect ratio all diamond tips formed by focused ion beam for conducting atomic force microscopy”, Journal of Vacuum Science Technology B, 17(4), 1999, pp. 1570-1574.
[11] S. Matsui, T. Kaito, J, Fujita, et al., “Three-dimensional nanostructure fabrication by focused-ion-beam chemical vapor deposition”, Journal of Vacuum Science Technology B, 18(6), 2000, pp. 3181-3184.
[12] A. Ostendorf, G. Kamlage, B. Chichkov, “Precise deep drilling of metal by femtosecond laser pulses”, Riken Review, no. 50, January 2003, pp. 87-89.
[13] M. Meunier, B. Fisette, A. V. Kabashin, “Processing of metals and semiconductors by a femtosecond laser-based microfabrication system”, SPIE USE, vol. 6, pp. 4978-32.
[14] M. Madou, Fundamentals of Microfabrication, CRC Press, New York, 1997, pp. 1-34.
[15] P. Rai-Choudhury, ed., Handbook of Microlithography, Micromachining, and Microfabrication: Volume I, SPIE, 1997, pp. 139-320.
[16] Y. D. Park, K. B. Jung, M. Overberg, et al., “Comparative study of Ni nanowires patterned by electron-beam lithography and fabricated by lift-off and dry etching techniques”, Journal of Vacuum Science Technology B, vol. 18, no. 1, 2000, pp. 16-20.
[17] M. Madou, Fundamentals of Microfabrication, CRC Press, New York, 1997, pp. 37-41.
[18] R. E. Howard, W. J. Skocpol, L. D. Jackel, “Nanostructures”, Annual Review Material Science, vol. 16, 1986, pp. 441-466.
[19] H Schultz, H. C. Scheer, et al., “New polymer for nanoimprinting”, Journal of Vacuum Science Technology B, 18, 4, 2000, pp. 1861-1865.
[20] K. P. Rajurkar, “Technology and Research in EDM”, Society of Manufacturing Engineers, Technical Papers, 1990, MS90-428 pp 1-13.
[21] K. P. Rajurkar, W. M. Wang, “Real-Time Stochastic Model and Control of EDM”, Annals of the CIRP, Vol. 39-1, 1990, pp 187-190.
[22] K. P. Rajurkar, W. M. Wang, J. A. McGeough, “WEDM Identification and Adaptive Control for Variable-Height Components”, Annals of the CIRP, Vol. 43-1, 1994 pp 119-202.
[23] B. Wei, K. P. Rajurkar, “Abrasive Electrodischarge Grinding of Superalloys and Ceramics”, Society of Manufacturing Engineers, Technical Papers, 1995, MR95-188, pp 1-9.
[24] Z. Y. Yu, K. P. Rajurkar, H. Shen, “High Aspect Ratio and Complex Shaped Blind Micro Holes by Micro EDM”, Annals of the CIRP, Vol 51-1, 2002 pp 359-362.
[25] Z. Y. Yu, J. Kozak, K. P. Rajurkar, “Modeling and Simulation of Micro EDM Process”, Annals of the CIRP, Vol. 52-1, 2003, pp 143-146.
[26] R. C. Drof, A. Kusiak, “Handbook of Design, Manufacturing, and Automation”, John Wiley & Sons, Inc., New York, 1994 pp 211-241.
[27] K. P. Rajurkar, Z. Y. Yu, “3D Micro-EDM Using CAD/CAM”, Annals of the CIRP, vol. 49-1, 2000, pp 127-130.
[28] G. Binning, H. Rohrer, “Scanning Tunneling Microscopy”, IBM J. of Res. Develop, vol. 44, no 1/2, 2000.
[29] H. Neddermeyer, “Scanning Tunneling Microscopy of Semiconductor Surfaces”, Reports on Progress in Physics, vol. 59, no. 6, 1996 pp 701-769.
[30] F. Besenbacher, “Scanning Tunneling Microscopy of Metal Surfaces”, Reports on Progress in Physics, vol. 59, no. 12, 1996 pp 1737-1802.
[31] D. Drakova, “Scanning Tunneling Microscopy”, Reports on Progress in Physics, vol. 60 no. 2, 1996, pp 180-245.
[32] D. Drakova, “Theoretical modelling of scanning tunneling microscopy, scanning tunneling spectroscopy and atomic force microscopy”, Reports on Progress in Physics, vol. 64, February 2001, 205-290.
[33] Nobuyuki Aoki, Keizo Fukuhara, Tomoyuki Kikutani et al., “Fabrication of buried metal dot structure in split-gate wire by scanning tunneling microscope,” Japanese Journal of Applied Physics, Part 1: Regular Papers & Short Notes & Review Papers 35 (6B), 3738-3742 (1996).
[34] M. Kemerink, K. Sauthoff, P. M. Koenraad et al., presented at the 2nd International Conference on Scanning Probe Spectroscopy, Jul. 19-22, 2000, Hamburg, 2001 (unpublished).
[35] Shigeru Kohmoto, Hitoshi Nakamura, Tomonori Ishikawa et al., “STM probe-assisted site-control of self-organized InAs quantum dots on GaAs surfaces,” Journal of Electronic Materials 29 (5), 525-529 (2000).
[36] Julia Kunze, Vincent Maurice, Lorena H. Klein et al., “In situ STM study of the anodic oxidation of Cu(0 0 1) in 0.1 M NaOH,” Journal of Electroanalytical Chemistry 554-555 (1), 113-125 (2003).
[37] Hitoshi Nakamura, Shigeru Kohmoto, Tomonori Ishikawa et al., presented at the Self-Organized Processes in Semiconductor Alloys, Nov. 29-Dec. 2, 1999, Boston, Mass., USA, 2000 (unpublished).
[38] Hitoshi Nakamura, Shigeru Kohmoto, Tomonori Ishikawa et al., “Novel nano-scale site-controlled InAs quantum dot assisted by scanning tunneling microscope probe,” Physica E: Low-Dimensional Systems and Nanostructures MSS9: The 9th International Conference on Modulated Semiconductor Structures, Jul. 12-Jul. 16, 1999 7 (3), 331-336 (2000).
[39] Xinxian Bao, Haifeng Chen, and Zhongfan Liu, presented at the Micro- and Nano-Photonic Materials and Devices, Jan. 27-Jan. 28, 2000, San Jose, Calif., USA, 2000 (unpublished).
[40] S. Chen, L. M. Wang, H. C. Yang et al., “Etching of YBa2Cu3O surface by scanning tunneling microscope,” Physica B: Condensed Matter Proceedings of the 20th International Conference on Low Temperature Physics, Aug. 4-11, 1993 194-96 (pt 1), 391-392 (1994).
[41] J. S. Chen, J. Cousty, J. Charlier et al., “Nanografting of N-vinyl-2-pyrrolidone molecules on a graphite surface with a scanning tunneling microscope,” Langmuir 12 (13), 3252-3256 (1996).
[42] C. Devlin and S. Chiang, presented at the Proceedings of the 1997 ACS San Francisco Meeting, Apr. 13-17, 1997, San Francisco, Calif., USA, 1997 (unpublished).
[43] Y. Hasegawa and Ph. Avouris, “Manipulation of the reconstruction of the Au(111) surface with the STM,” Science 258 (5089), 1763-1765 (1992).
[44] Chen-Jen Hung, Jianian Gui, and Jay A. Switzer, “Scanning probe nanolithography of conducting metal oxides,” Applied Physics Letters 71 (12), 1637-1639 (1997).
[45] Julia Kunze, Vincent Maurice, Lorena H. Klein et al., “In situ STM study of the anodic oxidation of Cu(0 0 1) in 0.1 M NaOH,” Journal of Electroanalytical Chemistry 554-555 (1), 113-125 (2003).
[46] C. Lebreton and Z. Z. Wang, “Nanofabrication on gold surface with scanning tunneling microscopy,” Microelectronic Engineering Proceedings of the 1995 International Conference on Micro- and Nanofabrication, Sep. 25-29, 1995 30 (1-4), 391-394 (1996).
[47] Hiroyuki Maruyama, Nobuyuki Kosai, Tadatake Sato et al., “Nanometer-scale lithography on the oligosilane Langmuir-Blodgett film,” Japanese Journal of Applied Physics, Part 1: Regular Papers & Short Notes & Review Papers 36 (12A), 7312-7316 (1997).
[48] Hiroyuki Maruyama, Nobuyuki Kosai, and Kazuyoshi Tanaka, “Nanometer-scale hole- and bit-modifications of oligosilane- and stearic acid-Langmuir-Blodgett films,” Thin Solid Films 338 (1-2), 155-160 (1999).
[49] Wataru Mizutani, Junji Inukai, and Masatoshi Ono, “Making a monolayer hole in a graphite surface by means of a scanning tunneling microscope,” Japanese Journal of Applied Physics, Part 2: Letters 29 (5), 815-817 (1990).
[50] K. Uesugi, T. Kurosu, M. Iida et al., presented at the 23rd International Conference on Solid State Devices and Materials—SSDM '91, Aug. 27-29, 1991, Yokohama, Jpn, 1991 (unpublished).
[51] K. Uesugi and T. Yao, “Nanometer-scale fabrication on graphite surfaces by scanning tunneling microscopy,” Ultramicroscopy Proceedings of the 6th International Conference on Scanning Tunneling Microscopy—STM '91, Aug. 12-16, 1991 42-44 (Part B), 1443-1445 (1992).
[52] Takashi Ohmori, Raul J. Castro, and Carlos R. Cabrera, “Surface modification of MoSe₂ in solution using a combined technique of scanning tunneling microscopy indentation with electrochemical etching,” Langmuir 14 (21), 6287-6290 (1998).
[53] H. Qiu, Y.-F. Lu, and Z.-H. Mai, “Nanostructure formation on amorphous WO₃ thin films in air by scanning tunneling microscopy,” Japanese Journal of Applied Physics, Part 1: Regular Papers and Short Notes and Review Papers 40 (1), 290-294 (2001).
[54] J. H. Davies, “The Physics of Low-dimensional Semiconductors: An Introduction”, Cambridge University Press, 1997.

What is claimed is:

1. An apparatus for nano-scale electric discharge machining of a conductive workpiece, comprising:
a. a dielectric medium deposited on a surface of the workpiece to form a dielectric layer having a thickness, T;
b. a positioning device capable of moving in three dimensions;
c. an electrode having a nano-scaled tip and mounted to the positioning device, wherein in operation the nano-scaled tip can be positioned over the surface of the workpiece to define a distance, D, therebetween the nano-scaled tip and the surface of the workpiece;
d. a power source electrically coupled with the electrode and the workpiece; and
e. a controller in communication with the positioning device for generating a signal to cause the nano-scaled tip of the electrode to move to a desired position over the surface of the workpiece,
wherein in operation a biasing voltage over a threshold voltage is applied from the power source between the nano-scaled tip of the electrode and the surface of the workpiece such that an avalanche current is formed across the nano-scaled tip of the electrode and the surface of the workpiece to perform machining of the workpiece.

2. The apparatus of claim 1, wherein the avalanche current comprises electrons forming a column of plasma between the nano-scaled tip of the electrode and the surface of the workpiece, and the avalanche current is a function of the distance D between the nano-scaled tip of the electrode and the surface of the workpiece and the applied biasing voltage over a threshold voltage.

3. The apparatus of claim 2, further comprising an ampere meter electrically connected to the electrode and the workpiece for detecting the avalanche current.

4. The apparatus of claim 3, wherein the detected avalanche current is feedback to the controller for determining and monitoring the distance D.

5. The apparatus of claim 4, further comprising a display in communication with the controller for displaying a surface structure of the workpiece reconstructed from the detected avalanche current.

6. The apparatus of claim 1, wherein the dielectric medium is characterized by a dielectric strength and the threshold voltage is no smaller than the dielectric strength.

7. The apparatus of claim 1, wherein the power source comprises one of a DC power source, a pulsed DC and AC power source, and a combined DC, pulsed DC and AC power source.

8. The apparatus of claim 7, wherein the biasing voltage between the nano-scaled tip of the electrode and the surface of the workpiece is adjustable in a range of 10 mV to 100 V, preferably in a range of 300 mV to 30 V, and the frequency of the biasing voltage between the nano-scaled tip of the electrode and the surface of the workpiece is adjustable in a range of 0.01 microHz to 30 MHz.

9. The apparatus of claim 1, wherein the positioning device comprises piezoelectric actuators, P_{X}, P_{Y} and P_{Z}, for moving the electrode along X, Y and Z directions, respectively, wherein the X, Y and Z directions are perpendicular to each other with the X and Y directions defining an X-Y plane parallel to the surface of the workpiece and the Z direction perpendicular to the surface of the workpiece.

10. The apparatus of claim 9, wherein the positioning device is controllable by the controller to operate in a constant-height mode in which the position of the nano-scaled tip of the electrode is substantially maintained within the X-Y plane during operation.

11. The apparatus of claim 9, wherein the positioning device is controllable by the controller to operate in a constant-current mode in which the avalanche current is maintained at a substantially constant level during operation.

12. The apparatus of claim 1, further comprising means for flushing the dielectric medium.

13. The apparatus of claim 1, wherein the dielectric medium comprises a dielectric fluid having a dielectric constant regater than 5.

14. The apparatus of claim 13, wherein the dielectric medium comprises an electric discharge machining oil.

15. The apparatus of claim 13, wherein T≧D.

16. The apparatus of claim 13, wherein at least the avalanche current causes a nano-scale dimple formed on the surface of the workpiece, and the material corresponding to the nano-scale dimple is removed by the dielectric fluid.

17. The apparatus of claim 1, wherein the nano-scaled tip of the electrode is made of a material that is mechanically, chemically, electrically and biomedically compatible with the workpiece.

18. The apparatus of claim 17, wherein the material comprises platinum-iridium (Pt—Ir) or tungsten.

19. A method for nano-scale electric discharge machining of a conductive workpiece, comprising the steps of:
a. depositing a dielectric medium on a surface of the workpiece to form a dielectric layer having a thickness, T;
b. positioning an electrode with a nano-scaled tip over the surface of the workpiece at a desired position; and
c. applying a biasing voltage over a threshold voltage between the nano-scaled tip of the electrode and the surface of the workpiece such that an avalanche current is formed across the nano-scaled tip of the electrode and the surface of the workpiece to perform machining of the workpiece.

20. The method of claim 19, further comprising the steps of:
a. detecting the avalanche current; and
b. adjusting the position of the nano-scaled tip of the electrode according to the detected tunneling current.

21. The method of claim 19, further comprising the steps of:
a. reconstructing a surface structure of the workpiece from the detected avalanche current; and
b. displaying the surface structure of the workpiece.

22. The method of claim 19, wherein the biasing voltage is provided by one of a DC power source, a pulsed DC and AC power source, and a combined DC, pulsed DC and AC power source.

23. The method of claim 22, further comprising the step of adjusting the biasing voltage in a range of 10 mV to 100 V, preferably in a range of 300 mV to 30 V, with respect to the amplitude of the biasing voltage, and in a range of 0.01 microHz to 30 MHz with respect to the frequency of the biasing voltage.

24. The method of claim 19, wherein the positioning step is performed by piezoelectric actuators, P_{X}, P_{Y} and P_{Z}, each engaging with the electrode, respectively.

25. The method of claim 19, wherein the applying step is operated in a constant-height mode.

26. The method of claim 25, wherein when the nano-scaled tip of the electrode scans the surface of the workpiece, the position of the nano-scaled tip of the electrode is maintained substantially within an X-Y plane that is substantially parallel to the surface of the workpiece during operation.

27. The method of claim 19, wherein the applying step is operated in a constant-current mode.

28. The method of claim 27, wherein the avalanche current is maintained at a substantially constant level during operation.

29. The method of claim 19, further comprising the step of flushing the dielectric medium during and/or after machining of the workpiece.

30. An apparatus for nano-scale electric discharge machining of a conductive workpiece, comprising:
a. a dielectric medium deposited on a surface of the workpiece to form a dielectric layer having a thickness;
b. a plurality of electrodes, E₁, E₂, . . . and E_{N}, each electrode E_{I} having at least one nano-scaled tip, I=1, . . . , N, N being an integer greater than one;
c. means for moving the plurality of electrodes individually or in coordination so as to position each electrode E_{I} over a surface of the workpiece at a desired position; and
d. means for applying a biasing voltage over a threshold voltage between a corresponding electrode E_{I} and the surface of the workpiece, respectively, such that an avalanche current is formed across the nano-scaled tip of at least one of the plurality of electrodes and the surface of the workpiece to perform machining of the workpiece.

31. The apparatus of claim 30, further comprising:
a. means for measuring an avalanche current corresponding to each electrode E_{I} and the surface of the workpiece, respectively; and
b. a controller in communication with the moving means, the applying means and the measuring means for processing data received from the moving means, the biasing means and the measuring means so as to generate at least one control signal in response.

32. The apparatus of claim 31, wherein the measuring means comprises an ampere meter having a plurality of measuring channels, each measuring channel electrically connected to one of the plurality of the electrodes E₁, E₂, . . . and E_{N} and the workpiece for detecting a corresponding avalanche current.

33. The apparatus of claim 30, further comprising a display for displaying a surface structure of the workpiece reconstructed from the measured avalanche current.

34. The apparatus of claim 30, wherein the moving means comprises a plurality of piezoelectric actuators, P₁, P₂, . . . and P_{M}, wherein each piezoelectric actuator P_{J} engages with a corresponding electrode E_{I} and capable of moving the corresponding electrode E_{I} along X, Y and Z directions, respectively, wherein J=1, . . . , M, M is an integer and the total number of plurality of piezoelectric actuators, wherein the X, Y and Z directions are perpendicular to each other with the X and Y directions defining an X-Y plane parallel to the surface of the workpiece and the Z direction perpendicular to the surface of the workpiece.

35. The apparatus of claim 34, wherein M=N.

36. The apparatus of claim 30, further comprising means for flushing the dielectric medium.

37. The apparatus of claim 30, wherein the nano-scaled tip of each electrode E_{I} is made of a material that is mechanically, chemically, electrically and biomedically compatible with the workpiece.

38. The apparatus of claim 37, wherein the material comprises platinum-iridium (Pt—Ir) or tungsten.

39. An apparatus for nano-scale electric discharge machining of a conductive workpiece, comprising:
a. an electrode having a working end with a plurality of nano-scaled tips, wherein the plurality of nano-scaled tips are aligned at staggered length; and
b. a power source electrically coupled to the electrode and the workpiece for applying a biasing voltage between the electrode and the workpiece.

40. The apparatus of claim 39, wherein the plurality of nano-scaled tips of the electrode are spatially arranged in an array.

41. The apparatus of claim 39, wherein in operation a biasing voltage over a threshold voltage is generated from the power source between the longest nano-scaled tip of the electrode and the surface of the workpiece such that an avalanche current is formed across the longest nano-scaled tip of the electrode and the surface of the workpiece to perform machining of the workpiece, and wherein as the machining of the workpiece progresses and when the longest nano-scaled tip of the electrode is eroded, a next longest nano-scaled tip of the electrode is brought close to the surface of the workpiece to establish a new avalanche current to continue the machining of the workpiece.

42. The apparatus of claim 39, further comprising means for moving the electrode to a desired position.

43. The apparatus of claim 42, wherein the moving means comprises:
a. a controller for generating a signal representative of a distance in a direction; and
b. a piezoelectric actuator mounted to the electrode for operably moving the electrode the distance in the direction in responsive to the signal received from the controller,
wherein the direction corresponds to a direction perpendicular to the surface of the workpiece, a direction parallel to the surface of the workpiece, or a combination thereof.

44. The apparatus of claim 39, further comprising means for measuring the avalanche current across the electrode and the workpiece.

45. The apparatus of claim 39, wherein the difference in length from one tip to its neighbor tip of the nano-scaled tips of the electrode is variable.

46. A method for nano-scale electric discharge machining, comprising the steps of:
a. positioning an electrode having a working end with a plurality of nano-scaled tips over a surface of a workpiece, wherein the plurality of nano-scaled tips are aligned at staggered length;
b. applying a biasing voltage over a threshold voltage between the electrode and the surface of the workpiece such that an avalanche current is formed across the longest of the plurality of nano-scaled tips and the surface of the workpiece to perform machining of the workpiece;
c. moving a next longest nano-scaled tip of the electrode closer to the surface of the workpiece when the longest nano-scaled tip of the electrode is eroded; and
d. repeating steps (b) and (c) until the workpiece is machined.

47. The method of claim 46, wherein the plurality of nano-scaled tips of the electrode are spatially arranged in an array.

48. A method for nano-scale electric discharge interacting of a conductive workpiece, comprising the step of forming an avalanche current across a nano-scaled tip of an electrode and a surface of the workpiece to interact with the workpiece.

49. An apparatus for nano-scale electric discharge interacting of a conductive workpiece, comprising a nano-scaled tip associated with an electrode to form an avalanche current across the nano-scaled tip and a surface of the workpiece to interact with the workpiece.
